(19) United States
(12) Patent Application Publication
(10) Pub. No.: US 2022/0123525 A1
(43) Pub. Date: Apr. 21, 2022

(54) SEMICONDUCTOR LASER DIODE DEVICE AND MANUFACTURING METHOD THEREOF

(71) Applicant: QSI Inc., Cheonan-si (KR)

(72) Inventors: Jeong-Geun Kwak, Cheonan-si (KR); An Sik Choi, Cheonan-si (KR); TaeKyung Kim, Cheonan-si (KR)

(73) Assignee: QSI Inc., Cheonan-si (KR)

(21) Appl. No.: 17/475,645

(22) Filed: Sep. 15, 2021

(30) Foreign Application Priority Data
Oct. 16, 2020 (KR) 10-2020-0134106

(51) Int. Cl. H01S 5/227; H01S 5/343

(52) U.S. Cl. CPC H01S 5/2275; H01S 2304/04; H01S 5/3432; H01S 5/34353

(57) ABSTRACT

The present disclosure provides fabrication of a laser diode with reliability at a high temperature of 80° C. or more in a high-power single mode by a process of thinly growing a second upper clad (P clad) layer at 1 μm or less in primary growth, appropriately controlling an upper portion Wt to 1.5 μm or more and a lower portion Wb to 4.0 μm or less of the wave guide, and then compensating for a second upper clad layer to 0.5 μm or more in regrowth, in order to compensate for disadvantages of a high-power and high-reliability laser diode device with a thick second upper clad layer (P clad). A second upper clad regrowth layer is applied to reduce internal resistance and voltage and reduce heat generated in the device to increase a Kink and a COD power, thereby improving the performance of a high-power and high-reliability laser diode.

### CROSS-REFERENCE TO RELATED APPLICATIONS

This application claims the priority of Korean Patent Application No. 10-2020-0134106 filed on Oct. 16, 2020, in the Korean Intellectual Property Office, the disclosure of which is incorporated herein by reference.

### BACKGROUND OF THE INVENTION

### Field of the Invention

The present disclosure relates to a semiconductor laser diode device and a manufacturing method thereof used for optical devices such as a dust measurement sensor, a factory automation sensor, an optical recording medium, and a laser printer.

### Description of the Related Art

In recent years, at home and abroad, as interests in (micro) fine dust generation and environment are increased, diversification of particle-related application products is made. Particularly, as microfine dust with a size of PM 2.5 or less occurs at about 90% of the total share, a laser diode has been used as a lighting source of the dust sensor. The laser diode is used as a light source for detecting a dust sensor in various environmental fields for appliances, vehicles, industries, and the like, which requires dust detection performance at a small size of 2.5 μm or less and a high-temperature operation at 80° or more, and as a result, there is a need for development of high-power and high-reliability devices.

In order to obtain a device characteristic of the high-power and high-reliability laser diode, a second upper clad (P clad) layer of an epidermal layer is designed to be thickened, so that the light is absorbed by a contact (GaAs) layer having a high refractive index during laser oscillation to prevent light loss from occurring. Further, it is very important to design a wave guide according to a thickness of the second upper clad (P clad) layer. For example, when the wave guide is wide, a problem such as a multi-mode, a kink or a catastrophic optical damage (COD) may occur, and when the wavelength is too small, an internal resistance Rd or a voltage V is increased to generate the heat of the device.

In a method of manufacturing a laser diode wave guide in the related art, there are wet etching using a soluble chemical material, dry etching by reaction of plasma or gas, and the like. In the high-power and high-reliability laser diode with the thick second upper clad (P clad), it is difficult to use the two etching methods. First, in the case of wet etching, since an etching time is increased, an etching amount is increased laterally by an etching depth of the second upper clad (P clad). As a result, if the size of a lower portion Wb of the wave guide is adjusted, an upper portion Wt of the wave guide is narrowed, the resistance and the voltage of the device are increased, and thus, there is a problem that the power and the reliability are deteriorated. Second, in the case of dry etching, the sizes of the upper and lower portions of the wave guide may be accurately controlled, but since a sheet of wafer is progressed, the productivity is deteriorated and since the wave guide is perpendicular, it is not suitable for the regrowth process.

Accordingly, in the related art, in the case of a laser diode device of which a second upper clad (P clad) layer is designed to be thick, in order to improve the problems, the size of a sufficient upper portion Wt of the wave guide is primarily secured using dry etching, the size of a narrow lower portion Wb of the wave guide is secondarily secured using wet etching, and then a mesa shape suitable for the regrowth process is made.

However, when the device of which the second upper clad (P clad) layer is designed to be thick is dry-etched and then wet-etched, a high-power and high-reliability device may be manufactured, but there is a problem that in the dry etching, since one sheet of wafer is progressed, productivity is lowered, and after wet etching, the shape of a beam is distorted due to the imbalance of the wave guide.

As related prior arts, there are Korean Patent Registration No. 10-0287203 and the like, but in Korean Patent Registration No. 10-0287203, the upper clad layer is formed thicker and only a partial thickness is etched to form a ridge structure, so the above-described problems are still present.

The above-described technical configuration is the background art for helping in the understanding of the present invention, and does not mean a conventional technology widely known in the art to which the present invention pertains.

### SUMMARY OF THE INVENTION

In order to solve the problems, an object of the present disclosure is to improve productivity and device characteristics as compared with existing processes by a process of growing a second upper clad (P clad) layer to be thin in primary epidermal growth, preparing a narrow lower wave guide Wb and a sufficient upper wave guide Wt by wet etching, regrowing additionally the second upper clad (P clad) in a regrowth process to compensate for a thickness of the second upper clad (P clad). That is, an object of the present disclosure is to manufacture a high-power and high-reliability laser diode device without a kink by maintaining a thick second upper clad (P clad) through the regrowth of the second upper clad (P clad) to prevent a light adsorption loss on a contact (GaAs) layer and securing the size of the sufficient upper wave guide Wt to minimize an ohmic resistance and voltage, and securing the narrow lower wave guide Wb. Further, it is possible to improve defects with distortion of the beam by minimizing the asymmetry of the wave guide.

According to an aspect of the present disclosure, a semiconductor laser diode device consists of a lower clad layer, an active layer, a first upper clad layer, an etch stop layer, a second upper clad layer, and an anti-oxidation cap layer on a semiconductor substrate in sequence, as primary growth. The second upper clad (P clad) was thinly grown at a thickness of 1 μm or less to be manufactured as an appropriate wave guide by wet etching and in a regrowth process after wet etching, the thickness of the second upper clad (P clad) layer is secondarily regrown and compensated to provide a high-power and high-reliability device. Here, the anti-oxidation cap layer is thinly grown at 100 A to minimize a light loss by adsorption of a refractive index during oscillation.

According to the present disclosure, unlike a general high-power and high-reliability laser diode, in the primary growth, the second upper clad (P clad) layer was thinly grown and was wet etched using a soluble chemical material such as tartaric acid, ammonia, hydrochloric acid, and phosphoric acid, and then regrown after etching to compensate for the thickness. In addition, for grid matching of etch stop and regrowth, the etch stop layer used AlGaAs.

That is, the growth thickness and the etching depth of main layers of the present disclosure may be formed as follows.

In the primary growth, the etch stop layer AlGaAs is grown to 100 Å, and the second upper clad (P clad) layer is grown thereon to 1 μm or less. In addition, the cap layer GaAs is grown to 100 Å or less for preventing AI oxidation in AlGaAs. A growth thickness error between the main layers may be within ±10%.

As such, when the primary growth is completed, the anti-oxidation layer and the second upper clad (P clad) layer are etched using a dielectric film mask such as silicon oxide (SiOx) or silicon nitride (SiNx) to form a wave guide. At this time, in order to make a single mode without a Kink, a lower wave guide is formed at 4 μm or less and in order to lower the resistance and the voltage, an upper wave guide is sufficiently formed at 1.5 μm or more. The main etch depth and the length error of the wave guide may be within ±10%.

Further, after the wave guide is formed, a current blocking layer AlGaAs is grown at 0.5 μm in secondary regrowth and the dielectric film mask is removed, and then a second upper clad regrowth layer AlGaAs is grown at 0.5 μm in a tertiary regrowth process and a contact layer GaAs is grown at 3 μm. The growth thickness error of the main layers may be within ±10%.

Further, the semiconductor laser diode device of the present disclosure includes a double barrier separate confinement heterostructure (DBSCH) capable of preventing carrier overflow and current leakage and controlling a far field vertical (FFV) mode by adding a barrier layer between the active layer and the first upper clad.

Further, the active layer includes an AlGaAs double quantum well (DQW) and is undoped.

Further, the structure of the high-power and high-reliability laser diode was applied with a selective buried ridge process.

According to the present disclosure, the thickness of the second upper clad (P clad) is maintained at about 1.5 μm to be suitable for high power and high reliability through the regrowth process of the second upper clad (P clad), and an area of the lower wave guide Wb is small as 2.0 to 4.0 μm and an area of the upper wave guide Wt may be designed to be sufficiently large as 1.5 μm or more while applying wet etching.

As the device characteristics result, while the lower wave guide Wb is designed to be narrow, Kink and the power of the device may be improved, and while the upper wave guide Wt is designed to be sufficiently wide, the resistance and the voltage may be lowered. Further, due to the resistance reduction of the device, the heat generation of the device is reduced and the light absorption does not occur during the oscillation, thereby manufacturing a high-reliability device.

Further, unlike a process of simultaneously applying dry etching and wet etching in the related art, in the present disclosure, while only wet etching is applied, a distortion phenomenon of the beam by asymmetry of the wave guide is improved during oscillation.

The effects were as follows when the device was driven under evaluation conditions of room temperature, a light power of 10 mW, and a continuous wave (CW) input current.

When comparing the present disclosure (second upper clad regrowth+wet etching) with the related art (only second upper clad+wet etching), a voltage Vop was reduced by 23% and a resistance Rd was reduced by about 50%.

Further, Kink was increased by 60% and a COD power was increased by 20%.

The process (second upper clad regrowth) of the present disclosure is applied to secure sufficiently the upper portion Wt of the wave guide and reduce the contact resistance Rd, thereby preventing the deterioration of the high-power laser, and when the lower portion Wb of the wave guide is controlled to be sufficiently narrow, a Kink level was improved.

When comparing beam shapes between the related art (only second upper clad+dry etching+wet etching) and the present disclosure (second upper clad regrowth+wet etching), in the present disclosure, a distortion phenomenon of the beam was improved as illustrated in FIG. 7 while the asymmetry of the wave guide was improved.

Additionally, when the reliability of the device was measured under evaluation conditions of a high temperature of 85° C., an optical power of 10 mW, and an automatic power control (APC) input current, a high-reliability device was obtained with a mean time to failure (MTTF) of the laser diode of 96,708 hours as illustrated in FIG. 6.

According to the present disclosure, the regrowth process of the second upper clad (P clad) is applied to control appropriately the area of the wave guide, thereby improving a contact resistance, a driving voltage, a beam shape, a Kink, and a COD power to secure the performance of a high-power and high-reliability laser diode in a single mode.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic diagram of a high-power and high-reliability semiconductor laser diode according to a second upper clad (P clad) regrowth method of the present disclosure;

FIG. 2 is a schematic diagram of a laser diode according to the related art (only second upper clad+wet etching);

FIGS. 3A through 3F are illustrating a fabrication process of manufacturing a high-power and high-reliability laser diode applied with a second upper clad (P clad) regrowth method of the present disclosure;

FIG. 4 is graphs showing a voltage and a resistance at room temperature according to the present disclosure;

FIG. 5A is a graph showing Kink and power at room temperature according to the prior art;

FIG. 5B is a graph showing Kink and power at room temperature according to the present disclosure;

FIG. 6A is a graph showing reliability at a high temperature according to the present disclosure;

FIG. 6B is a graph showing reliability at a high temperature according to the present disclosure; and

FIG. 7A is a graph showing characteristics of a beam according to the prior art.

FIG. 7B is a graph showing characteristics of a beam in the present disclosure.

### DETAILED DESCRIPTION OF THE PREFERRED EMBODIMENT

Hereinafter, a preferred embodiment of the present disclosure will be described in detail with reference to the accompanying drawings.

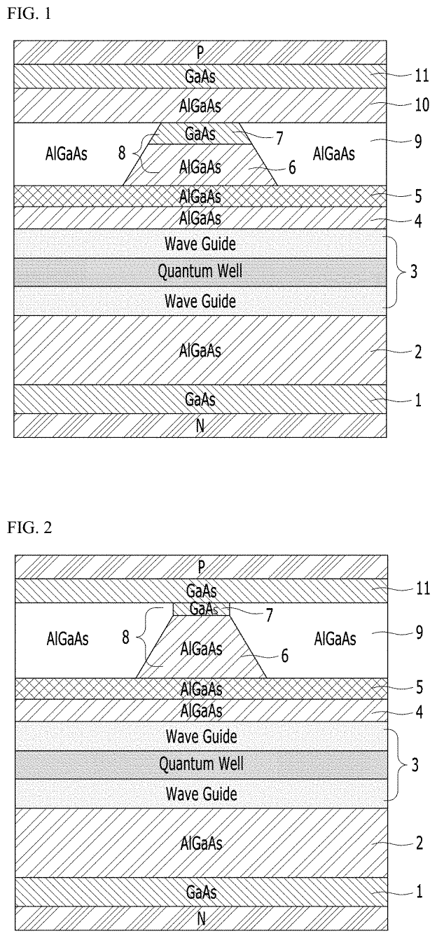

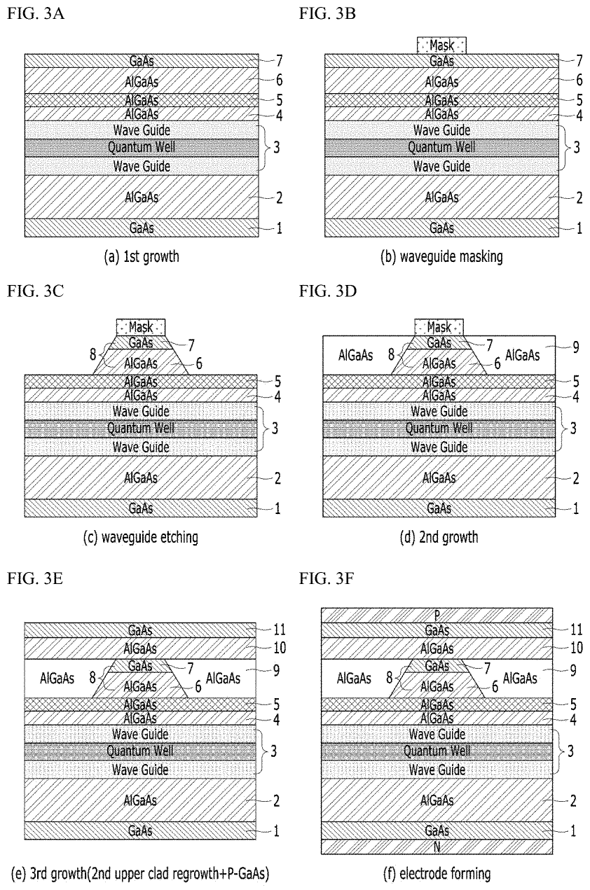

FIG. 1 is a cross-sectional view of a schematic diagram of improving a high-power and high-reliability device of which a second upper clad is thick through the second upper clad (P clad) regrowth according to an embodiment of the present disclosure. The high-power and high-reliability device consists of a lower clad layer 2, an active layer 3, a first upper clad layer 4, an etch stop layer 5, a second upper clad layer 6, and an anti-oxidation layer 7 on a compound semiconductor substrate 1 in sequence.

When describing a material and a growth order of primary growth of the high-power and high-reliability laser diode in detail, the substrate 1 consists of an n-type GaAs compound semiconductor. In this case, the lower clad layer 2 consists of n-type AlxGaAs (Alx composition is 0.5 to 0.6) and the doping of the lower clad layer 2 is performed at a concentration of 1E-18 cm². A dopant of the lower clad layer 2 uses silicon. In addition, tellurium (TE) and selenium (SE) dopants may be used.

The active layer 3 consists of an AlxGaAs double quantum well (DQW) and is undoped. Two quantum wells were used to increase the number of carriers. In order to prevent carrier overflow and current leakage and control an FFV mode, the active layer 3 is constituted in a double barrier separate confinement heterostructure (DBSCH) of adding a barrier between the active layer and the clad.

The first upper clad layer 4 consists of p-type AlxGaAs (Alx composition is 0.4 to 0.6) and doped at 1E+18 cm′ or more. A dopant of the first upper clad layer 4 uses carbon, zinc, magnesium (Mg), or beryllium (Be).

The etch stop layer 5 for making the wave guide enables selective wet etching using a material with a high Alx composition as AlxGaAs. In addition, finally, GaAs is thinly formed at 1.0E+18 cm′ or more by doping at 1 μm so as not to affect a refractive index of the second upper clad (P clad) regrowth layer while preventing the Alx oxidation of the primary growth. In this order, the primary growth is completed.

The following is an order of a fabricating process of the high-power and high-reliability laser diode.

A wave guide mask is prepared on a wafer in which the primary growth is completed using a dielectric film (SiOx, SiNx) and the anti-oxidation layer 7 and the second upper clad layer 6 are etched through wet etching to form a mesa-shaped wave guide 8. As current blocking layer 9, p-type AlxGaAs (Alx composition is 0.6 to 0.7) is selectively grown on the side surface of the wave guide using metal organic chemical vapor deposition (MOCVD) through a dielectric film mask and doped at 1E+18 cm′ or more. In order to remove the wave guide mask and compensate for the second upper clad layer thinly grown in the primary growth, as a second upper clad regrowth layer 10, p-type AlxGaAs (Alx composition is 0.5 to 0.6) is grown and doped at 1.5E+19 cm⁻³ or more. Subsequently, p-type GaAs as a contact layer 11 is grown on the second upper clad regrowth layer 10 and doped at 1.5E+19 cm⁻³ or more. Finally, p and n-type metals are deposited to form an electrode.

There is an advantage of improving the performance of the laser by minimizing the internal resistance and the heat loss of the high-reliability laser diode through the EPI structure and the FAB process technique.

That is, according to the present disclosure, in a semiconductor laser diode device module including the lower clad, the active layer, and the upper clad in sequence, the structure of the upper clad was newly designed. The upper clad layer consists of two first and second layers, but the second upper clad layer forming the mesa structure is thinly formed to form a mesa structure having a relatively gentle tapered shape even though forming the wave guide of the mesa structure by wet etching, and the small thickness of the second upper clad layer is compensated by thinly forming the regrowth layer of the second upper clad layer on the wave guide with the mesa structure.

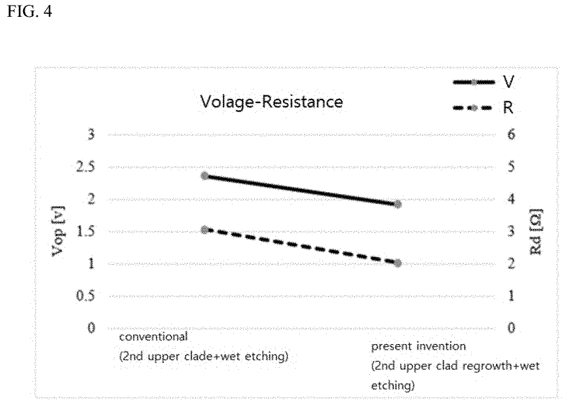

The high-power and high-reliability laser diode fabricated according to the embodiment of the present disclosure obtained the results illustrated in FIGS. 4 to 7.

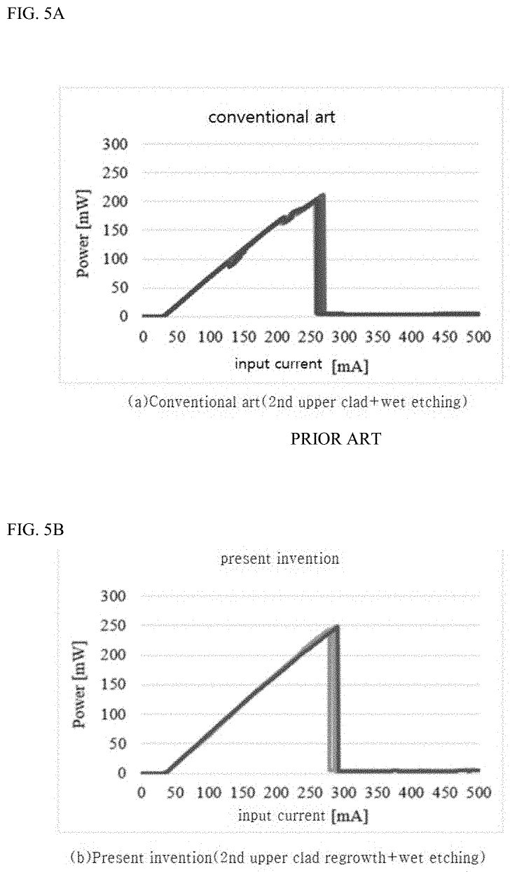

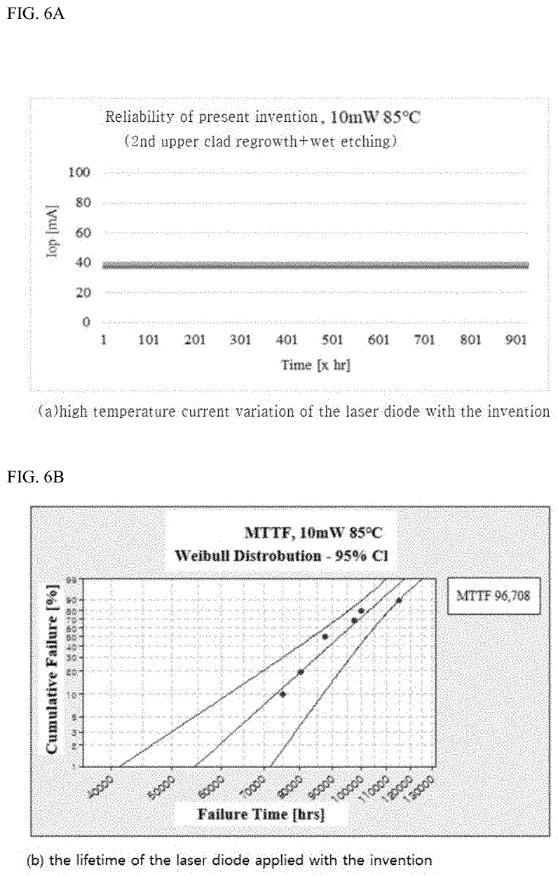

That is, as compared with the related art, it can be confirmed that the driving voltage and resistance of the laser diode device of the present disclosure are lowered as illustrated in FIG. 4, and it was shown that the laser diode device may reach high reliability having higher power and longer life (FIGS. 5B, 6A and 6B).

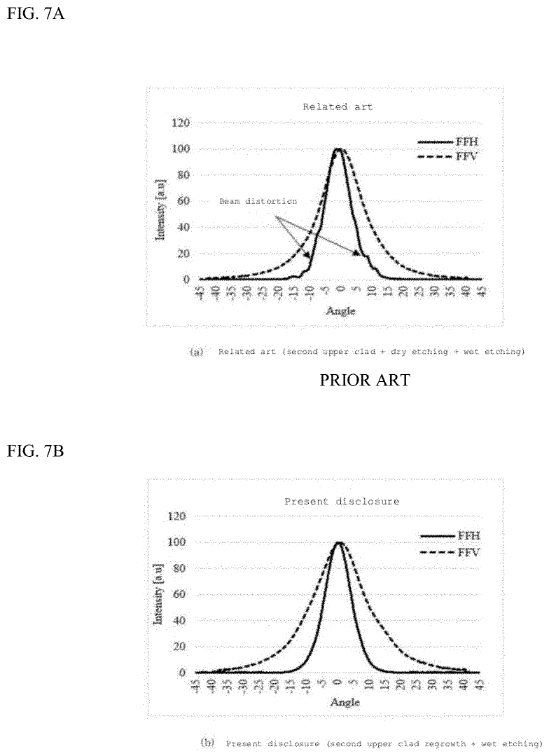

In addition, in the related art, a distortion phenomenon of the beam generated by the asymmetry of the wave guide may be improved by the present disclosure (FIGS. 7A and 7B).

Further, as compared with the related art (only second upper clad+dry etching+wet etching), in the present disclosure (second upper clad regrowth+wet etching), only the wet etching is applied once to reduce the number of etching times and many wafers may be performed at the same time to improve productivity.

The scope of the present disclosure is not limited to the AlGaAs series described above and can be applied even to InGaAlP series. That is, even in the design of the second upper clad and the wave guide design control of the InGaAlP-based laser diode device, when the second upper clad regrowth process is introduced in the same manner as described above, the resistance and the voltage are improved during the operation, and the Kink and the COD power are increased to fabricate a high-power and high-reliability laser diode device. The InGaAlP-based laser diode device includes a lower clad InGaAlP, an active layer InGaP, and an upper clad InGaAlP.

It will be apparent that the scope of the present disclosure is not limited to the embodiments described above and defined by those disclosed in the appended claims, and those skilled in the art can make various modification and changes within the scope disclosed in the appended claims.

What is claimed is:

1. A semiconductor laser diode device comprising:
a semiconductor substrate;
a lower clad layer formed on the semiconductor substrate;
an active layer formed on the lower clad layer;
a first upper clad layer formed on the active layer;
an etch stop layer formed on the first upper clad layer;
a second upper clad layer formed on the etch stop layer; and
an anti-oxidation layer formed on the second upper clad layer, as primary growth,
a mesa wave guide formed by partially removing the anti-oxidation layer and a current blocking layer through a mask; and
a current blocking layer formed on a side surface of the wave guide, as secondary growth,
a second upper clad regrowth layer formed by removing the mask; and
a contact layer continuously formed on the second upper clad regrowth layer, as a tertiary growth.

2. The semiconductor laser diode device of claim 1, wherein the second upper clad layer is thinly grown at a thickness of 1.0 μm or less and the second upper clad regrowth layer is grown to compensate for the thickness of the second upper clad layer by the second upper clad regrowth layer for high power and high reliability.

3. The semiconductor laser diode device of claim 1, wherein an AlGaAs barrier with a high refractive index is inserted into the active layer to have a double barrier separate confinement heterostructure (DBSCH) of slightly controlling a far field vertical (FFV) mode.

4. The semiconductor laser diode device of claim 1, wherein the semiconductor laser diode device is a high-power and high-reliability semiconductor laser diode device in a single mode and has a mesa wave guide structure.

5. The semiconductor laser diode device of claim 1, wherein the first upper clad layer, the second upper clad layer, and the second upper clad regrowth layer are doped at 1E+18 cm⁻³ or more by using carbon, magnesium (Mg), beryllium (Be) or zinc as a dopant.

6. The semiconductor laser diode device of claim 1, wherein the substrate and the lower clad layer are doped at 1E+18 cm⁻³ or more by using silicon, tellurium (TE) or selenium (SE) as a dopant.

7. The semiconductor laser diode device of claim 1, wherein the anti-oxidation layer is thinly formed at a thickness of 100 Å or less between the second upper clad layer and the second upper clad regrowth layer to be grown without affecting a mode due to a refractive index.

8. The semiconductor laser diode device of claim 1, wherein the active layer includes AlGaAs double quantum well (DQW) and is undoped.

9. The semiconductor laser diode device of claim 1, wherein the etch stop layer is selectively wet-etched with an Alx composition of 0.8 or more as AlGaAs.

10. The semiconductor laser diode device of claim 1, wherein the semiconductor laser diode device has a selective buried ridge structure of growing the current blocking layer, the second upper clad regrowth layer, and the contact layer with MOCVD after constituting the wave guide.

11. The semiconductor laser diode device of claim 2, wherein the second upper clad layer is thinly grown on ESL at 1 μm or less, and
the second upper clad regrowth layer is grown on the anti-oxidation layer and the current blocking layer at 0.5 μm or less and an error of a growth thickness is within ±10%.

12. The semiconductor laser diode device of claim 2, wherein a width of a lower wave guide is narrowed to 2.0 to 4.0 and a width of a upper wave guide is 1.5 μm or more.

13. A manufacturing method of a semiconductor laser diode device with high power and high reliability comprising:
a primary growth step of forming a lower clad layer on a semiconductor substrate,
forming an active layer on the lower clad layer,
forming a first upper clad layer on the active layer,
forming an etch stop layer on the first upper clad layer,
forming a second upper clad layer on the etch stop layer, and
forming an anti-oxidation layer on the second upper clad layer;
a secondary growth step of forming a mesa-shaped wave guide by preparing and disposing a wave guide mask on a wafer in which a primary growth is completed using a dielectric film and etching the anti-oxidation layer and the second upper clad layer through wet etching, and
selectively growing a current blocking layer on a side surface of the wave guide using metal organic chemical vapor deposition (MOCVD) through a dielectric film mask; and
a tertiary growth step of removing the wave guide mask and growing a second upper clad regrowth layer to compensate for a thickness of the second upper clad layer grown in the primary growth,
continuously growing a contact layer on the second upper clad regrowth layer, and
depositing p and n-type metals to form an electrode.

14. A semiconductor laser diode device module comprising a lower clad, an active layer, and an upper clad in sequence, wherein
the upper clad comprises
a first upper clad layer;
a second upper clad layer formed in a mesa structure on an etch stop layer formed on the first upper clad layer; and
an anti-oxidation layer formed in a mesa structure on the second upper clad layer and a second upper clad regrowth layer formed on a current blocking layer formed on a side surface of the mesa structure to compensate from a thickness of the second upper clad layer.
